(19) United States
(12) Patent Application Publication
(10) Pub. No.: US 2026/0050106 A1
(43) Pub. Date: Feb. 19, 2026

(54) OPTICAL DEVICE WITH ANTIREFLECTION COATING FILM AND RECESSED SILICON MICROLENS

(71) Applicant: Taiwan Semiconductor Manufacturing Company, Ltd., Hsin-Chu (TW)

(72) Inventors: Yu Chia Lin, Taichung City (TW); Chia-Hsin Chen, Tainan City (TW); Chih-Tsung Tsai, Tainan City (TW); Zi-Jheng Liu, Taoyuan City (TW); Ju-Wei Wang, Hsinchu (TW); Tu-Hao Yu, Hsinchu (TW); Ming-Fa Chen, Taichung City (TW)

(21) Appl. No.: 18/970,422

(22) Filed: Dec. 5, 2024

Related U.S. Application Data
(60) Provisional application No. 63/684,611, filed on Aug. 19, 2024.

(51) Int. Cl. G02B 1/11; G02B 3/00; G02B 6/30; G03F 7/00

(52) U.S. Cl. CPC G02B 1/11; G02B 3/0037; G02B 6/30; G03F 7/0005

(57) ABSTRACT

A sacrificial component over a first side of a substrate. The sacrificial component has a curved profile. First etching processes are performed to the sacrificial component and the substrate from the first side, which remove the sacrificial component and defines a first portion of the substrate below the sacrificial component as a microlens. The microlens has a second curved profile. A mask layer is formed over the first side of the substrate to surround the microlens. The mask layer and the substrate have different material compositions. Second etching processes are performed to the mask layer and the substrate from the first side. The mask layer is etched at a slower rate than the substrate, such that the microlens has a smaller height than a second portion of the substrate below the mask layer after the second etching processes have been completed. The mask layer is then removed.

### PRIORITY DATA

The present application is a utility application of U.S. Provisional Patent Application No. 63/684,611, filed on Aug. 19, 2024, entitled “Microlens and Anti-reflective Coating Film For Optical Path”, the disclosure of which is hereby incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs. For example, microlenses and anti-reflective coating (ARC) films have been implemented on various structures, but the fabrication thereof has not been optimized. Consequently, the resulting structures may have sub-optimal performance and/or yield.

Therefore, although conventional methods of fabricating optical devices have generally been adequate, they have not been satisfactory in all aspects.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion.

FIG. 1A is a perspective view of an IC device according to various aspects of the present disclosure.

FIG. 1B is a planar top view of an IC device according to various aspects of the present disclosure.

FIG. 1C is a cross-sectional side view of an IC device according to various aspects of the present disclosure.

FIGS. 2-13 are cross-sectional views of various embodiments of an optical device at various stages of fabrication according to various aspects of the present disclosure.

FIG. 14 is a block diagram of a manufacturing system according to various aspects of the present disclosure.

FIG. 15 is a flowchart illustrating a method of fabricating a semiconductor device according to various aspects of the present disclosure.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “over,” “below,” “beneath,” “up,” “down,” “top,” “bottom,” etc., as well as derivatives thereof (e.g., “horizontally,” “downwardly,” “upwardly,” etc.) are used for ease of the present disclosure of one features relationship to another feature. The spatially relative terms are intended to cover different orientations of the device including the features. Still further, when a number or a range of numbers is described with “about,” “approximate,” and the like, the term is intended to encompass numbers that are within a reasonable range including the number described, such as within +/−10% of the number described or other values as understood by person skilled in the art. For example, the term “about 5 nm” encompasses the dimension range from 4.5 nm to 5.5 nm.

The present disclosure is generally related to semiconductor devices, and more particularly to optical devices formed using semiconductor fabrication processes. In more detail, optical devices (also referred to as photonic devices) may use light (as opposed to electrical signals) to transmit data. For example, computational results obtained by a graphical processing unit (GPU) or a central processing unit (CPU) may be transmitted via optical devices through light. Such an optical data transmission scheme is faster and/or more efficient than data transmission via purely electrical paths. In some applications, optical devices themselves may also be used to implement the GPUs or CPUs (or portions thereof).

However, optical devices fabricating using existing methods may still face certain challenges. For example, optical devices may utilize a polymer material to form its microlenses, which are used to focus light. Unfortunately, microlenses formed using polymer materials may place more stringent requirements on subsequent fabrication processes (e.g., limitations on temperature), and/or these polymer-based microlenses may be more prone to deformation or other potential defects. As a result, the polymer-based microlenses may suffer from poor performance, such as inability to focus the light on an intended target. In addition, optical devices formed by existing methods often lack antireflection films in certain locations, which in turn may increase an insertion loss of the optical devices, because optical energy may be unduly reflected and/or refracted away.

To address the various issues discussed above, the present disclosure provides a process flow for fabricating optical devices with silicon microlenses. In other words, the microlenses are formed as a part of a silicon wafer. As a result, the microlenses of the present disclosure have more mechanical/structural integrity, are less vulnerable to deformation, have less stringent requirements on subsequent fabrication processes, and offer better light focusing capabilities. Furthermore, the optical device of the present disclosure also utilize various antireflection films to reduce optical energy losses from unintended light reflection/refraction, and consequently, insertion loss is minimized.

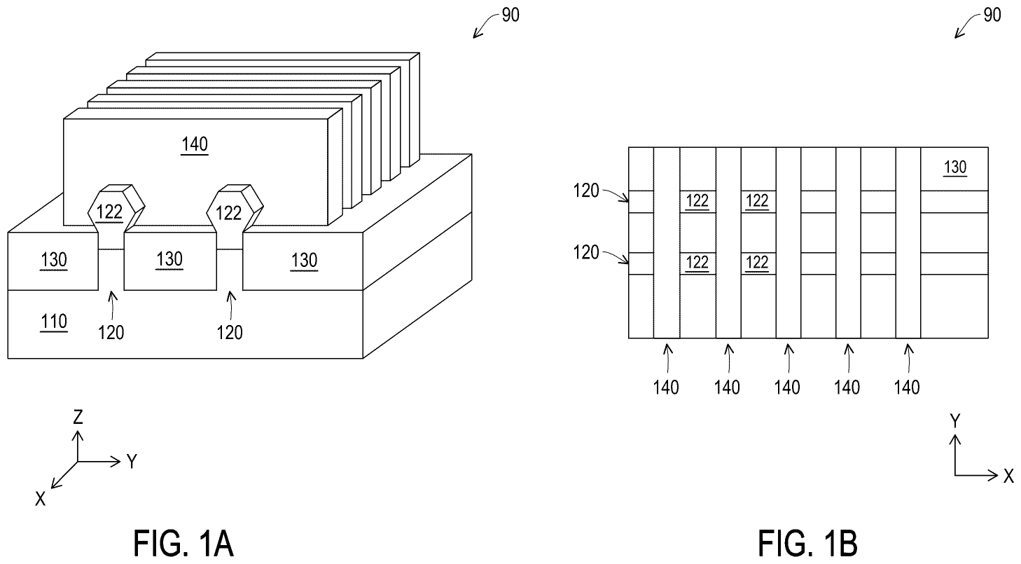

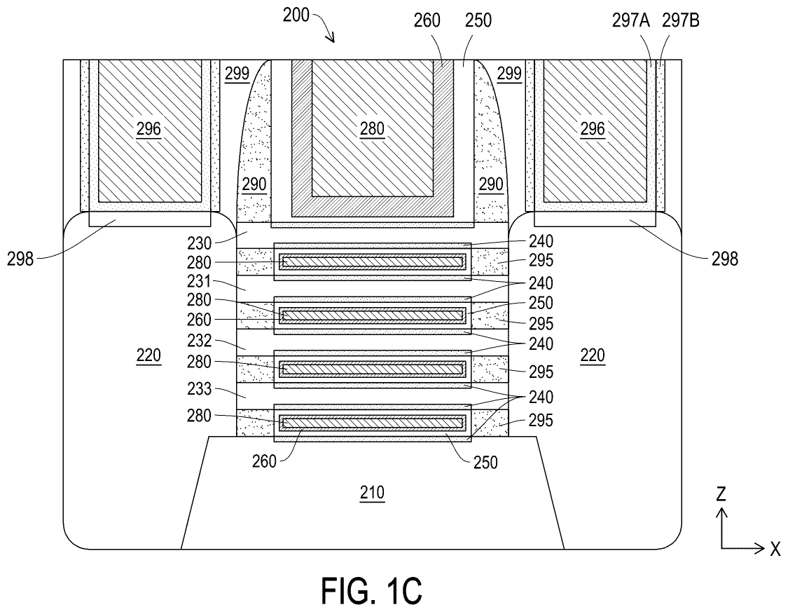

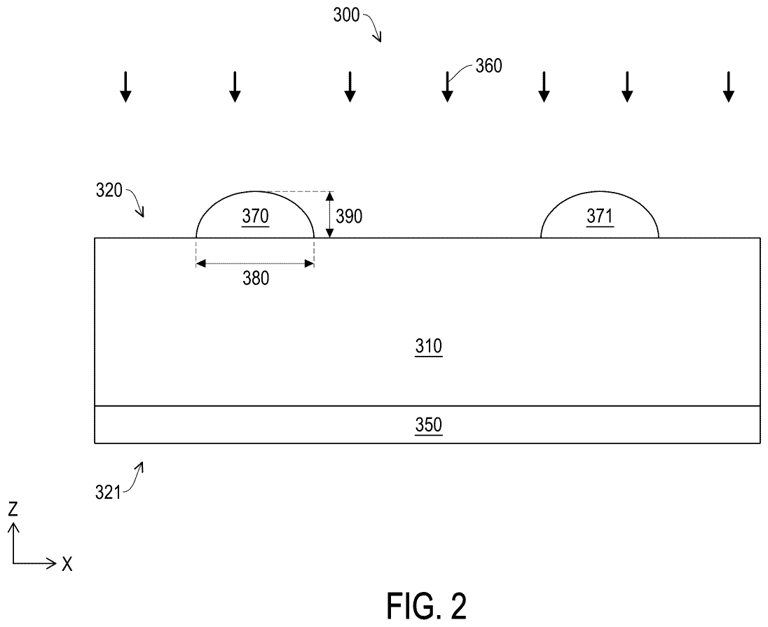

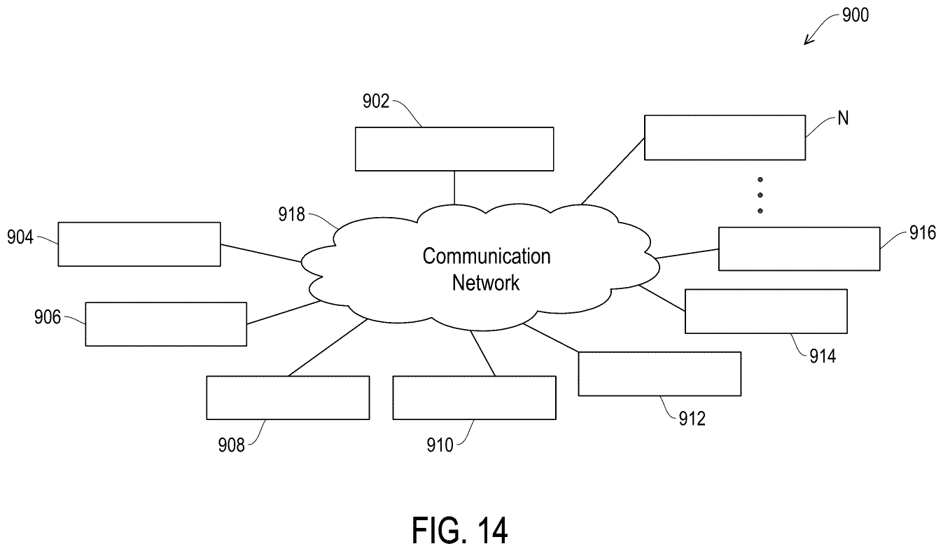

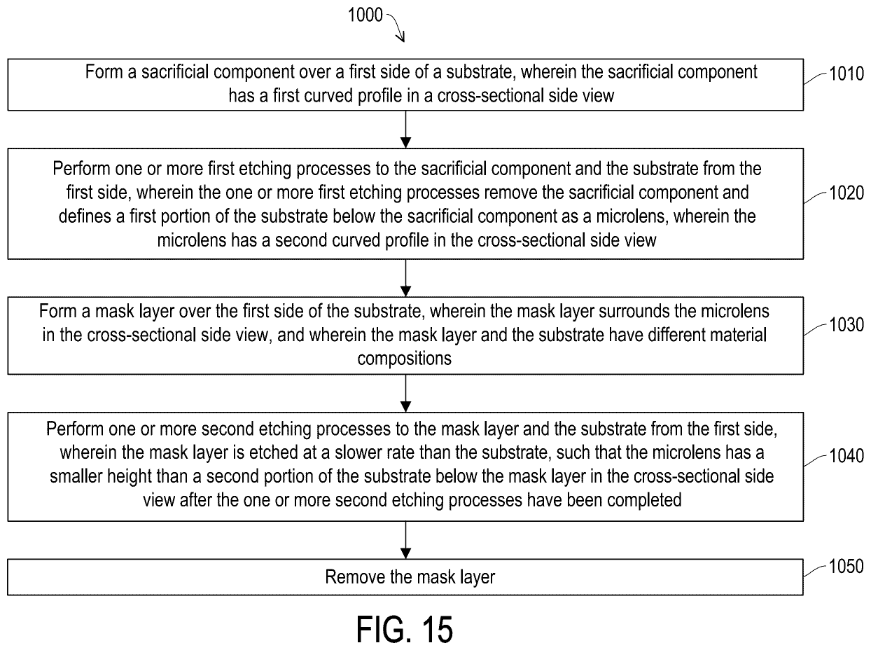

Various aspects of the present disclosure will now be discussed below with reference to FIGS. 1-15. Specifically, FIGS. 1A-1C describe example types of transistors that can be implemented on a device that includes an optical device, FIGS. 2-13 describe an example fabrication process flow used to fabricate an optical device according to an embodiment of the present disclosure, FIG. 14 describes an example fabrication system, and FIG. 15 describes a flowchart corresponding to a method of fabricating an optical device according to an embodiment of the present disclosure.

Referring now to FIGS. 1A-1B, a three-dimensional perspective view and a top view are illustrated, respectively, of a portion of an Integrated Circuit (IC) device 90. The IC device 90 may be an intermediate device fabricated during processing of an IC, or a portion thereof, that may comprise electronic memory circuits and/or other logic circuits, passive components such as resistors, capacitors, and inductors, and active components such as p-type FETs (PFETs), n-type FETs (NFETs), FinFETs, metal-oxide semiconductor field effect transistors (MOSFET), complementary metal-oxide semiconductor (CMOS) transistors, bipolar transistors, high voltage transistors, high frequency transistors, and/or other memory cells. The present disclosure is not limited to any particular number of devices or device regions, or to any particular device configurations, unless otherwise claimed. For example, although the IC device 90 as illustrated is a three-dimensional FinFET device, the concepts of the present disclosure may also apply to planar FET devices or GAA devices.

As shown in FIG. 1A, the IC device 90 includes a substrate 110. The substrate 110 may comprise an elementary (single element) semiconductor, such as silicon, germanium, and/or other suitable materials; a compound semiconductor, such as silicon carbide, gallium arsenic, gallium phosphide, indium phosphide, indium arsenide, indium antimonide, and/or other suitable materials; an alloy semiconductor such as SiGe, GaAsP, AlInAs, AlGaAs, GaInAs, GaInP, GaInAsP, and/or other suitable materials. The substrate 110 may be a single-layer material having a uniform composition. Alternatively, the substrate 110 may include multiple material layers having similar or different compositions suitable for IC device manufacturing. In one example, the substrate 110 may be a silicon-on-insulator (SOI) substrate having a semiconductor silicon layer formed on a silicon oxide layer. In another example, the substrate 110 may include a conductive layer, a semiconductor layer, a dielectric layer, other layers, or combinations thereof. Various doped regions, such as source/drain regions, may be formed in or on the substrate 110. The doped regions may be doped with n-type dopants, such as phosphorus or arsenic, and/or p-type dopants, such as boron, depending on design requirements. The doped regions may be formed directly on the substrate 110, in a p-well structure, in an n-well structure, in a dual-well structure, or using a raised structure. Doped regions may be formed by implantation of dopant atoms, in-situ doped epitaxial growth, and/or other suitable techniques.

Three-dimensional active regions 120 are formed on the substrate 110. The active regions 120 are elongated fin-like structures that protrude upwardly out of the substrate 110. As such, the active regions 120 may be interchangeably referred to as fins 120 or fin structures 120 hereinafter. The fin structures 120 may be fabricated using suitable processes including photolithography and etch processes. The photolithography process may include forming a photoresist layer overlying the substrate 110, exposing the photoresist to a pattern, performing post-exposure bake processes, and developing the photoresist to form a masking element (not shown) including the resist. The masking element is then used for etching recesses into the substrate 110, leaving the fin structures 120 on the substrate 110. The etching process may include dry etching, wet etching, reactive ion etching (RIE), and/or other suitable processes. In some embodiments, the fin structure 120 may be formed by double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. As an example, a layer may be formed over a substrate and patterned using a photolithography process. Spacers are formed alongside the patterned layer using a self-aligned process. The layer is then removed, and the remaining spacers, or mandrels, may then be used to pattern the fin structures 120.

The IC device 90 also includes source/drain features 122 formed over the fins 120. The source/drain features 122 may include epi-layers that are epitaxially grown on the fin structures 120. The IC device 90 further includes isolation structures 130 formed over the substrate 110. The isolation structures 130 electrically separate various components of the IC device 90. The isolation structures 130 may include silicon oxide, silicon nitride, silicon oxynitride, fluoride-doped silicate glass (FSG), a low-k dielectric material, and/or other suitable materials. In some embodiments, the isolation structures 130 may include shallow trench isolation (STI) features. In one embodiment, the isolation structures 130 are formed by etching trenches in the substrate 110 during the formation of the fin structures 120. The trenches may then be filled with an isolating material described above, followed by a chemical mechanical planarization (CMP) process. Other isolation structure such as field oxide, local oxidation of silicon (LOCOS), and/or other suitable structures may also be implemented as the isolation structures 130. Alternatively, the isolation structures 130 may include a multi-layer structure, for example, having one or more thermal oxide liner layers.

The IC device 90 also includes gate structures 140 formed over and engaging the fins 120 on three sides in a channel region of each fin 120. The gate structures 140 may be dummy gate structures (e.g., containing an oxide gate dielectric and a polysilicon gate electrode), or they may be HKMG structures that contain a high-k gate dielectric and a metal gate electrode, where the HKMG structures are formed by replacing the dummy gate structures. Though not depicted herein, the gate structure 140 may include additional material layers, such as an interfacial layer over the fins 120, a capping layer, other suitable layers, or combinations thereof.

Referring to FIG. 1B, multiple fins 120 are oriented lengthwise along the X-direction, and multiple gate structure 140 are oriented lengthwise along the Y-direction, i.e., generally perpendicular to the fins 120. In many embodiments, the IC device 90 includes additional features such as gate spacers disposed along sidewalls of the gate structures 140, hard mask layer(s) disposed over the gate structures 140, and numerous other features.

FIG. 1C illustrates a diagrammatic cross-sectional side view of a portion of an IC device 200 fabricated according to embodiments of the present disclosure, where the IC device 200 is a gate-all-around (GAA) device and may be referred to as a GAA device 200 hereinafter. It is understood that the GAA device 200 may be an NFET in some embodiments, or it may be a PFET in other embodiments.

Referring to FIG. 1C, the cross-sectional view of the GAA device 200 is taken along an X-Z plane, where the X-direction (same X-direction as in FIG. 1A) is the horizontal direction, and the Z-direction (same Z-direction as in FIG. 1A) is the vertical direction. The GAA device 200 includes a fin structure 210, which may be similar to the fin structure 120 discussed above. In some embodiments, the fin structure 210 includes silicon. The GAA device 200 includes source/drain features 220, which may be similar to the source/drain features 122 discussed above. In embodiments where the GAA device 200 is an NFET, the source/drain features 220 include silicon phosphorous (SiP). In embodiments where the GAA device 200 is a PFET, the source/drain features 220 include silicon germanium (SiGe).

The GAA device 200 includes a plurality of channels, for example channels 230-233 as shown in FIG. 1C. The channels 230-233 each include a semiconductive material, for example silicon or a silicon compound. The channels 230-233 are nanostructures (e.g., having sizes that are in a range of a few nanometers) and may also each have an elongated shape and extend in the X-direction. In some embodiments, the channels 230-233 may each have a nano-wire shape, a nano-sheet shape, a nano-tube shape, etc. The cross-sectional profile of the nano-wire, nano-sheet, or nano-tube may be round/circular, square, rectangular, hexagonal, elliptical, or combinations thereof.

In some embodiments, the lengths (e.g., measured in the X-direction) of the channels 230-233 may be different from each other. For example, a length of the channel 230 may be less than a length of the channel 231, which may be less than a length of the channel 232, which may be less than a length of the channel 233. In some embodiments, each of the channels 230-233 may not have uniform thicknesses.

In some embodiments, a spacing (e.g., measured in the Z-direction) between the channels 230-233 (each channel from adjacent channels) is in a range between about 2 nanometers (nm) and about 12 nm. In some embodiments, a thickness (e.g., measured in the Z-direction) of each of the channels 230-233 is in a range between about 5 nm and about 2 nm. In some embodiments, a width (e.g., measured in the Y-direction of FIG. 1A) of each of the channels 230-233 is in a range between about 15 nm and about 150 nm. A plurality of interfacial layers (ILs) 240 may also be formed on the upper and lower surfaces of the channels 230-233.

The GAA device 200 also includes gate structures that are disposed over and in between the channels 230-233. The gate structures may include gate dielectric layers 250. In some embodiments, the gate dielectric layers 250 include a high-k gate dielectric. The gate structures further include one or more work function metal layers 260. In embodiments where the GAA device 200 is an NFET, the one or more work function metal layers 260 include N-type work function metal layers, such as TiAlC. In embodiments where the GAA device 200 is a PFET, the one or more work function metal layers 260 include P-type work function metal layers, such as TiN.

The gate structures also include fill metals 280. In the portion of the gate structure formed over the channels 230-233, the fill metal 280 are formed over the one or more work function metal layers 260. The one or more work function metal layers 260 have a U-shape and wrap around the fill metal 280, and the gate dielectric layer 250 also has a U-shape and wrap around the one or more work function metal layers 260. In portions of the gate structures formed between the channels 230-233, the fill metal 280 is circumferentially surrounded (in the cross-sectional view) by the one or more work function metal layers 260, which is then circumferentially surrounded by the gate dielectric layer 250. It is understood that the gate structures may also include a glue layer that is formed between the one or more work function metal layers 260 and the fill metal 280 to increase adhesion. However, for reasons of simplicity, such a glue layer is not specifically illustrated herein.

The GAA device 200 also includes gate spacers 290 and inner spacers 295 that are disposed on sidewalls of the gate dielectric layer 250. The inner spacers 295 are also disposed between the channels 230-233. The gate spacers and the inner spacers 295 may include a dielectric material, for example a low-k material such as SiOCN, SiON, SiN, or SiOC.

The GAA device 200 further includes source/drain contacts 296 that are formed over the source/drain features 220. The source/drain contacts 296 may include a conductive material such as cobalt, copper, aluminum, tungsten, or combinations thereof. The source/drain contacts 296 are surrounded by barrier layers, for example barrier layers 297A and 297B, which help prevent or reduce diffusion of materials from and into the source/drain contacts 296. In some embodiments, the barrier layer 297A includes TiN, and the barrier layer 297B includes SiN. A silicide layer 298 may also be formed between the source/drain features 220 and the source/drain contacts 296, so as to reduce the source/drain contact resistance. The silicide layer 298 may contain a metal silicide material, such as cobalt silicide in some embodiments.

The GAA device 200 further includes an interlayer dielectric (ILD) 299. The ILD 299 provides electrical isolation between the various components of the GAA device 200, for example between the gate structures and the source/drain contacts 296.

The FinFET devices and GAA devices discussed above may be implemented in photonic applications. The fabrication of photonic applications may involve microlenses and ARC films. However, the microlens fabrication method is not well established, and its implementation on silicon wafers may be difficult. In addition, structures without ARC films may result in high insertion loss due to energy losses from reflection and/or refraction. To address these issues, the present disclosure pertains to a microlens and ARC film design that can create an optical in/out path in advanced silicon-photonic package product with low insertion loss. For example, the present disclosure forms the optical in/out device (e.g., a silicon microlens) on a silicon wafer. The present disclosure also designs a multi-layer ARC film scheme on the silicon wafer's frontside and backside, as will be discussed below in more detail.

FIGS. 2-13 illustrate diagrammatic fragmentary cross-sectional side views of a portion of an optical device 300 at various stages of fabrication according to embodiments of the present disclosure. Each of the cross-sectional side views is taken along an X-direction (as the horizontal direction) and a Z-direction (as the vertical direction). Referring now to FIG. 2, the optical device 300 at this stage of fabrication includes a silicon substrate 310, which is a part of a silicon wafer. The optical device 300 has a side 320 and a side 321 opposite the side 320 in the vertical Z-direction. The side 320 may also be referred to as a front side, while the side 321 may be referred to as a back side.

One or more layers 350 are formed over the side 321 of the silicon substrate 310. For example, the one or more layers 350 may include one or more circuit layers (e.g., circuits comprising the FinFET devices and/or the GAA devices discussed above with reference to FIGS. 1A-1C). These circuit layers may be configured to control certain aspects of the operation of the optical device 300, and/or to carry out certain computational tasks. The one or more layers 350 may also include one or more antireflection coating (ARC) films. The ARC films may reduce a reflection or refraction of light, which in turns helps to better focus light on its intended target better and reduce an insertion loss. The one or more layers 350 may also include certain markers or marks (e.g., copper markers), which may be used to provide alignment between the optical device 300 and other devices that may be coupled to the optical device 300. The one or more layers 350 may also include a protection layer. The protection layer may help to protect the components of the optical device 300 from contaminants, moisture, mechanical deformation, etc. In some embodiments, the protection layer may include a silicon oxide layer. In other embodiments, the protection layer may include another type of suitable dielectric material. The protection layer may have a thickness of about 2000 angstroms in some embodiments.

The silicon substrate 310 may also have a substantially flat or smooth surface (e.g., a surface with very little topography variations) on the side 320. For example, a planarization process, such as a chemical mechanical polishing (CMP) process, may have been performed on the surface of the silicon substrate 310 that is exposed to the side 320.

A process 360 is then performed to form a plurality of sacrificial components, such as sacrificial components 370 and 371, over the surface of the silicon substrate 310 exposed to the side 320. In some embodiments, the process 360 includes a lithography process. In other embodiments, the process 360 includes a dispensing process. In some embodiments, the sacrificial components may have a material that is similar to a material of the silicon substrate 310, such that they have the same or substantially similar etching rate for an upcoming etching process. In other embodiments, the sacrificial components may include a polymer material, such as a photoresist material.

Regardless of the particular type of process used to form the sacrificial components 370 and 371, or the specific material compositions of the sacrificial components 370 and 371, it is understood that the process parameters of the process 360 are configured to tune the profile of the sacrificial components 370 and 371, such that the sacrificial components 370 and 371 may each be substantially curved in the cross-sectional side view of FIG. 2. It is also understood that the flatness of the topography of the surface of the silicon substrate 310 exposed to the side 320 may help to improve the radius of curvature (NU %) of the sacrificial components 370 and 371. The curved cross-sectional profile of the sacrificial components 370 and 371 resembles the curved profile of a desired microlens, because the sacrificial components 370 and 371 will be utilized to define the microlenses of the optical device 300, as discussed below in more detail.

The sacrificial components 370 and 371 may each have a width (e.g., a horizontal dimension measured in the X-direction, also referred to as a critical dimension) 380 and a height 390 (e.g., a vertical dimension measured in the Z-direction). In some embodiments, the width 380 is in a range between about 50 microns and about 150 microns, for example, about 100 microns. In some embodiments, the height 390 is in a range between about 2 microns and about 3.2 microns, for example, about 2.6 microns.

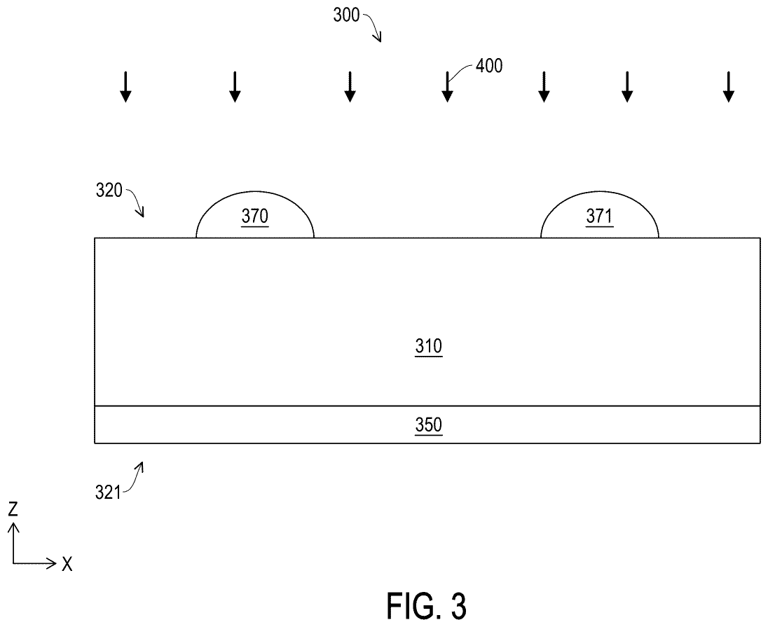

Referring now to FIGS. 3-5, an etching process 400 is performed to the optical device 300, so as to transfer the shape/profile of the sacrificial components 370 and 371 to portions of the silicon substrate 310 below. In more detail, as shown in FIG. 3, the etching process 400 may be performed to the optical device 300 from the side 320, while the sacrificial components 370 and 371 are still intact. In some embodiments, the etching process 400 includes an anisotropic etching process. In some embodiments, the anisotropic etching process includes an ICP-RIE (inductively coupled plasma reactive-Ion etching) process, in which the etchant is a fluorine-based etchant (e.g., CHF₃, CF₄, C₄F₈, NF₃, SF₆., or a mixture thereof). In some embodiments, the etchant may further include a reactive gas or a diluting gas (e.g., O₂, Ar, He, or a mixture thereof).

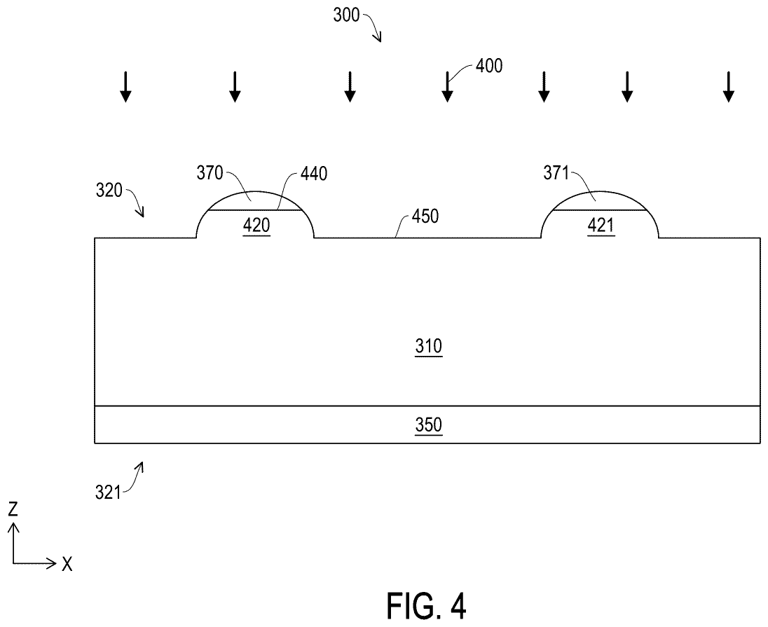

At the stage of fabrication shown in FIG. 4, the etching process 400 is ongoing, and the transferring of the cross-sectional profile of the sacrificial components 370 and 371 into portions 420 and 421 of the silicon substrate 310 is gradually taking place but not completed yet. For example, top portions of the sacrificial components 370 and 371 have been etched away by the etching process 400, but bottom portions of the sacrificial components 370 and 371 still remain. Meanwhile, the portion 420 of the silicon substrate 310 located directly below the sacrificial component 370 is now exhibiting curved side surfaces, as is the portion 421 of the silicon substrate 310 located directly below the sacrificial component 371. At this stage of fabrication, an interface 440 between the sacrificial component 370 and the portion 420 of the silicon substrate 310 (or a similar interface between the sacrificial component 371 and the portion 421 of the silicon substrate 310) may be located above (e.g., having a greater vertical elevation in the Z-direction) than an upper surface 450 of the rest of the silicon substrate 310 that is exposed to the side 320.

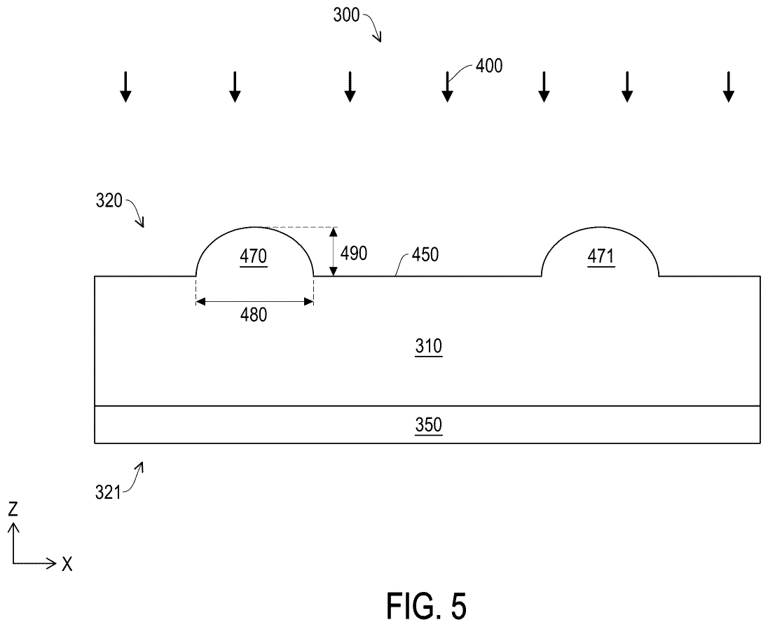

Referring now to FIG. 5, the sacrificial components 370 and 371 have been completed etched away by the etching process 400 at this stage of fabrication, and the curved cross-sectional view profiles of the sacrificial components 370 and 371 are transferred to portions of the silicon substrate 470 and 471, respectively, that are located directly below the sacrificial components 370 and 371. The portions 470 and 471 of the silicon substrate 310 may serve as microlenses, and as such, they may be interchangeably referred to as microlenses 470 and 471 hereinafter. The microlenses 470 and 471 may each have a width 480 (e.g., horizontal dimension measured in the X-direction). In some embodiments, the width 480 of the microlenses 470/471 is similar to the width 380 of the sacrificial components 370/371. For example, the width 480 of the microlenses 470/471 may be within 10% of the width 380 of the sacrificial components 370/371 in some embodiments.

The microlenses 470 and 471 also protrude outwardly in the Z-direction from the rest of the silicon substrate 310. Such a vertical protrusion may be defined as a height 490, which is measured from the topmost surface (or a topmost point) of the microlens 470 (or microlens 471) to the surface 450 of the silicon substrate 310 that is exposed to the side 320. In some embodiments, the height 490 of the microlenses 470/471 is similar to the height 390 of the sacrificial components 370/371. For example, the height 490 of the microlenses 470/471 may be within 10% of the height 390 of the sacrificial components 370/371 in some embodiments.

It is understood that although the curved shape of the microlenses 470 and 471 is defined based on the curved shape of the sacrificial components 370 and 371, respectively, the microlenses 470/471 need not necessarily have the same curved profiles as the sacrificial components 370/371. For example, the sacrificial components 370 or 371 may have a first degree of curvature, whereas the microlenses 470 or 471 may have a second degree of curvature that is different from the first degree of curvature. In some embodiments, the second degree of curvature may be greater than the first degree of curvature. In other embodiments, the second degree of curvature may be less than the first degree of curvature. In any case, it is understood that the degree of curvature of the microlenses 470 and 471 is still dependent on the degree of curvature of the sacrificial components 370 and 371, as well as the process parameters of the etching process 400. As such, the curved profiles of the sacrificial components 370 and 371, as well as the parameters of the etching process 400, may be configured carefully in order to achieve a desired degree of curvature for the microlenses 470 and 471 (or other aspects of the shape thereof), so that light can be accurately focused by the microlenses 470 and 471 onto their intended targets.

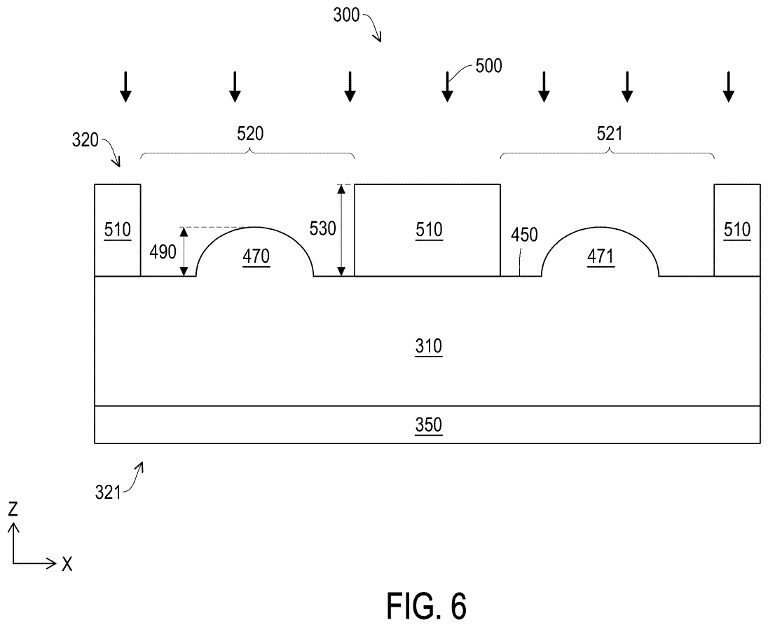

Referring now to FIG. 6, a process 500 is performed to form a mask layer 510 over portions of the surface 450 (exposed to the side 320) of the silicon substrate 310. A material of the mask layer 510 is configured to be different from the silicon substrate 310 (e.g., a significant etching selectivity exists between the material of the mask layer 510 and the silicon substrate 310). In some embodiments, the material of the mask layer 510 may include a metal. In some other embodiments, the material of the mask layer 510 may include a polymer (e.g., photoresist). The mask layer 510 may define recesses 520 and 521, within which the microlenses 470 and 471 are located.

In some embodiments, the mask layer 510 may be formed by a lithography process. For example, via a deposition process such as chemical vapor deposition (CVD), physical vapor deposition (PVD), atomic layer deposition (ALD), or combinations thereof, a continuous mask material layer may be deposited over the surface 450 of the silicon substrate 310, including over the surfaces of the microlenses 470 and 471. A lithography process may then be performed to the continuous mask material layer. The lithography process may include one or more pre-exposure baking, exposing, post-exposure baking, developing, rinsing processes, etc. (not necessarily performed in that order).

As a result of the lithography process, the continuous mask material layer is patterned into the mask layer 510 shown in FIG. 6, where different segments of the mask layer 510 surround the microlenses 470 and 471 laterally. Alternatively stated, each microlens 470 or 471 is surrounded on opposite sides by different segments of the mask layer 510. At this stage of fabrication, the mask layer 510 has a height 530 that is measured from a bottommost surface of the mask layer 510 (which may be substantially co-planar with the surface 450 of the silicon substrate 310) to an uppermost surface of the mask layer 510. In some embodiments, the height 530 of the mask layer 510 is greater than the height 490 of the microlenses 470 and 471. This is evident in FIG. 6, where the uppermost surface (exposed to the side 320) of the mask layer 510 has a greater vertical elevation in the Z-direction than the uppermost surface (exposed to the side 320) of the microlenses 470 or 471.

Note that the fact that the microlenses 470 and 471 have a silicon material composition is one of the inherent results of the unique fabrication process flow of the present disclosure. For example, rather than forming the microlenses with a layer of a different material composition (e.g., polymer), the present disclosure defines portions of the silicon substrate 310 to form the microlenses 470 and 471 with the help of sacrificial components 370 and 371. In other words, the microlenses 470 and 471 are carved out of the silicon substrate 310 and therefore inherently has a same material composition as the silicon substrate 310, as opposed to having a non-polymer material composition.

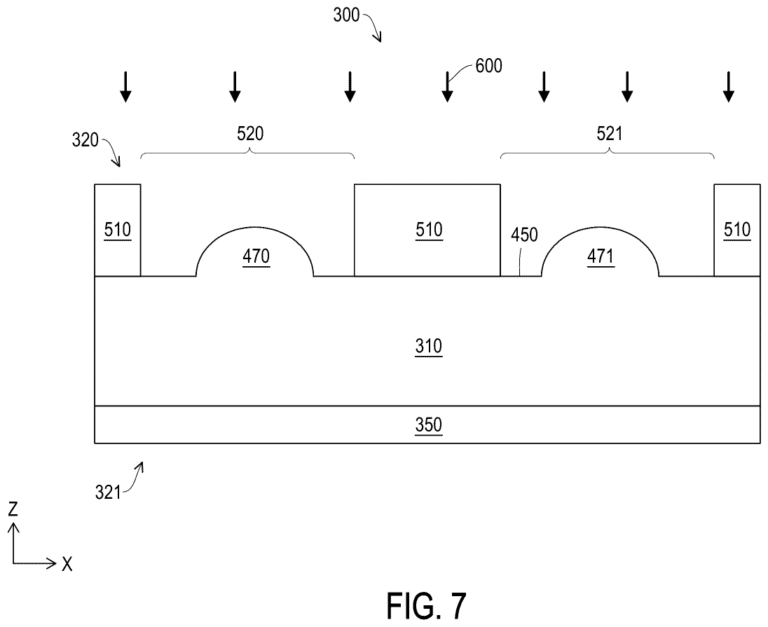

Referring now to FIGS. 7-9, an etching process 600 is performed to the optical device 300 from the side 320 to further extend the recesses 521 and 521 downwards vertically in the Z-direction. In some embodiments, the etching process 600 includes an anisotropic etching process. As discussed above, the different material compositions between the mask layer 510 and the silicon substrate 310 (e.g., metal versus silicon) allows a significant etching selectivity to be achieved between the mask layer 510 and the silicon substrate 310 during the etching process 600. For example, the various process parameters (e.g., the type of etchant) of the etching process 600 may be configured such that the silicon substrate 310 may be etched away at a substantially faster rate (e.g., 10 times or more) than the mask layer 510. In this manner, the mask layer 510 may serve as a protective layer during the etching process 600, such that the portions of the silicon substrate 310 disposed directly below the mask layer 510 are protected from being etched away by the etching process 600, while the portions of the silicon substrate 310 exposed to the side 320 (i.e., not protected by the mask layer 510) are gradually removed.

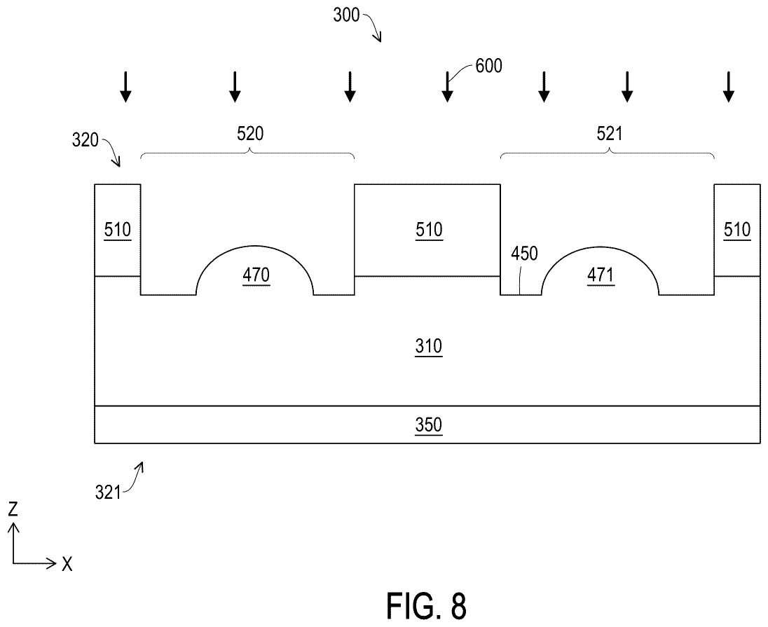

In the stage of fabrication of FIG. 7, the etching process 600 has just begun, and almost no portion of the silicon substrate 310 has been etched away yet, regardless of whether they are protected by the mask layer 510 or not. By the stage of fabrication of FIG. 8, the etching process 600 has removed some portions of the silicon substrate 310 not protected by the mask layer 510, including the microlenses 470 and 471, since they are exposed to the side 320 as well. Note that the etching rate with respect to the microlenses 470 and 471 and the rest of the exposed portions of the silicon substrate 310 may be similar, since the microlenses 470 and 471 and the rest of the silicon substrate 310 may have the same material composition (e.g., both having a silicon composition). As such, the curved cross-sectional view profile of the microlenses 470 and 471 may be at least partially preserved, despite the microlenses 470 and 471 being etched by the etching process 600.

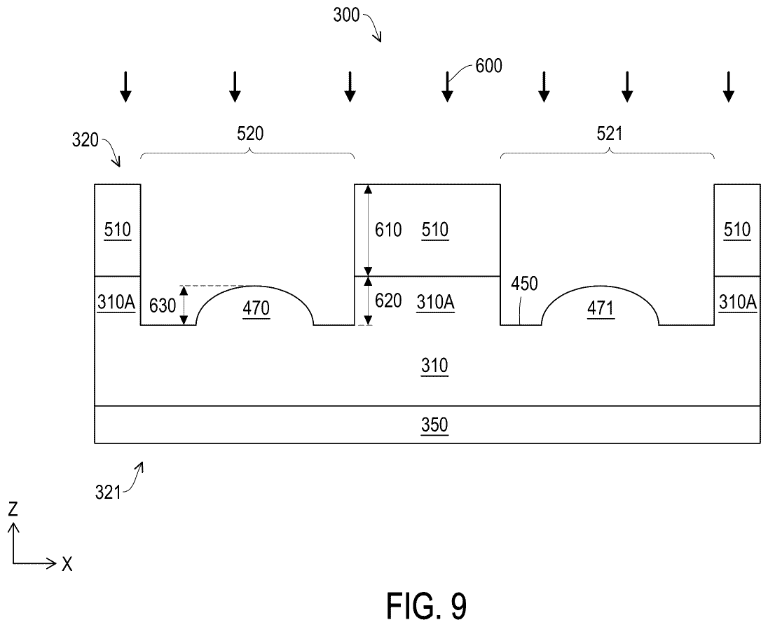

By the stage of fabrication shown in FIG. 9, a sufficient amount of the silicon substrate 310 and the microlenses 470 and 471 have been removed, and the etching process 600 may stop. At this point, the remaining portions of the mask layer 510 each have a thickness 610, which may be smaller than or equal to the height 530 of the mask layer 510 before the etching process 600 is performed, since the etching process 600 may have etched away a small amount of the mask layer 510. The remaining portions 310A of the silicon substrate 310 that are directly under the mask layers may each have a height 620, which is measured from the surface 450 of the silicon substrate 310 exposed to the side 320 and an interface between the mask layer 510 and the silicon substrate 310 in the Z-direction.

Meanwhile, the microlenses 470 and 471 at the completion of the etching process 600 may each have a height 630, which is also measured from the flat surface 450 of the silicon substrate 310 exposed to the side 320 and an uppermost point of the microlens 470 or 471 in the Z-direction. The height 630 may be smaller than the height 490 of the microlenses 470 and 471 before the etching process 600 is performed, since the etching process 600 may have etched away a slightly greater amount of the microlenses 470 and 471 than a rest of the silicon substrate 310 not protected by the mask layer 510. The height 630 of the microlenses 470 and 471 is also configured to be smaller than the height 620 of the remaining portions 310A of the silicon substrate 310 directly under the mask layer 510. This is done so that the remaining portions 310 of the silicon substrate 310 may help protect the microlenses 470 and 471 from damage or contamination in later fabrication processes, as will be discussed in more detail below.

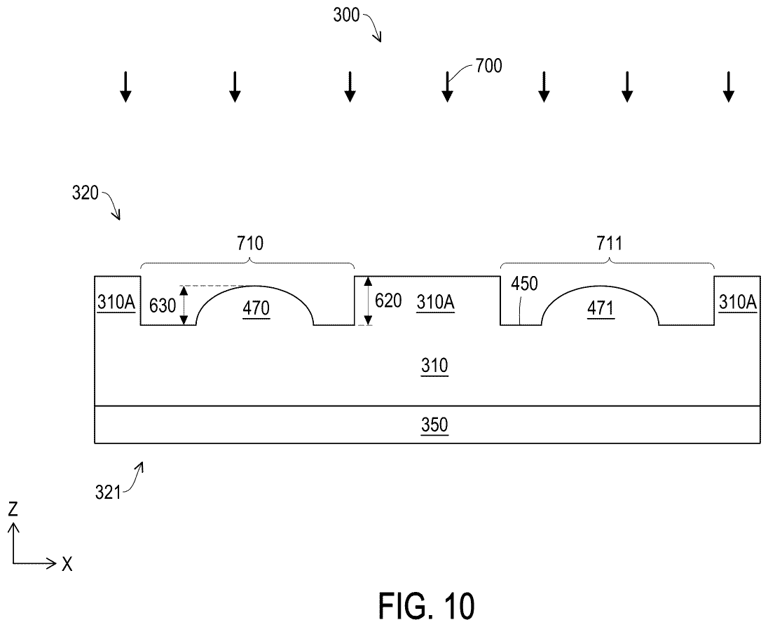

Referring now to FIG. 10, a removal process 700 is performed to the optical device 300 to remove the mask layer 510. In some embodiments, the removal process 700 includes one or more etching process that may be configured with a high etching selectivity between the material of the mask layer 510 (e.g., metal) and the material of the silicon substrate 310. In other words, such an etching process may be configured to etch away the material of the mask layer 510 at a substantially faster rate than the material of the silicon substrate 310. In other embodiments where the mask layer 510 contains a photoresist material, the removal process 700 may include a stripping process or an ashing process configured to remove the photoresist material.

Regardless of the details of the removal process 700, the end result is that recesses, such as recess 710 and 711 (e.g., as remnants of the recesses 520 and 521 after the removal of the mask layer 510), may be formed in the optical device 300. The recesses 710 and 711 are defined by portions 310A of the silicon substrate 310 (which protrude vertically out in the Z-direction toward the side 320) and a rest of the silicon substrate 310. The microlens 470 is located within the recess 710, while the microlens 471 is located within the recess 711, which is an inherent result of the unique fabrication processes of the present disclosure being performed. For example, the etching processes 600 are performed with the mask layer 510 serving as a protective mask to ensure that the portions 310A of the silicon substrate 310 (which partially define the recesses 710 and 711) are taller than the microlenses 470 and 471.

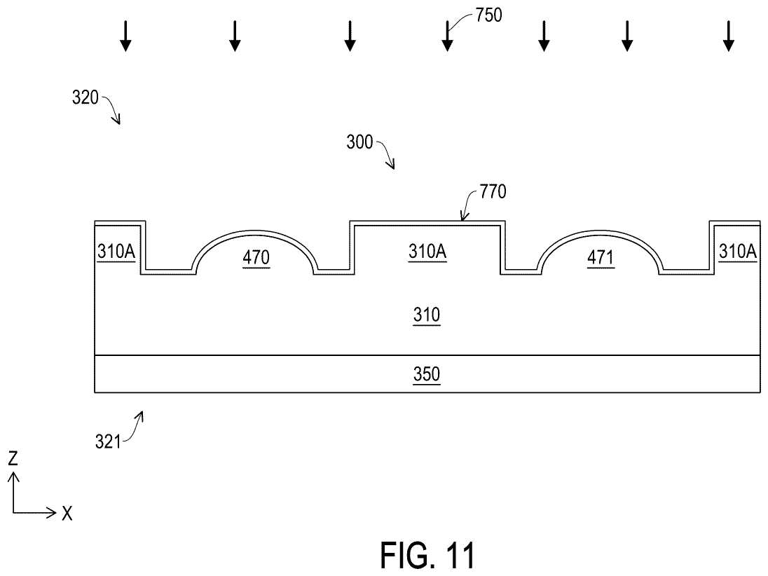

Referring now to FIG. 11, one or more deposition processes 750 may be performed to the optical device 300 to form an antireflection coating (ARC) layer 770 over the side 320 of the silicon substrate 310, including over the surfaces of the microlenses 470 and 471. In some embodiments, the ARC layer 770 is deposited in a conformal manner (e.g., having relatively uniform thicknesses throughout). In some embodiments, the ARC layer 770 may include a single type of material. In some embodiments, the ARC layer 770 may include multiples type of materials (e.g., having multiple layers of different materials). Some candidates for the materials of the ARC layer 770 are listed in the table below.

| ARC | Refractive | | |
|---|---|---|---|
| material type | index | X value | Y value |
| SiOxFy | 1.0~3.0 | 0-5 | 0-5 |
| SiOxBy | 1.0~3.0 | 0-5 | 0-5 |
| SiOxPy | 1.0~3.0 | 0-5 | 0-5 |
| SiOxNy | 1.0~3.0 | 0-5 | 0-5 |
| SiCxOy | 1.0~3.0 | 0-5 | 0-5 |
| SiCxNy | 1.0~3.0 | 0-5 | 0-5 |

It is understood that the candidate materials listed in the table above may also be used to implement the ARC films in the layers 350 formed on the side 321 of the silicon substrate 310.

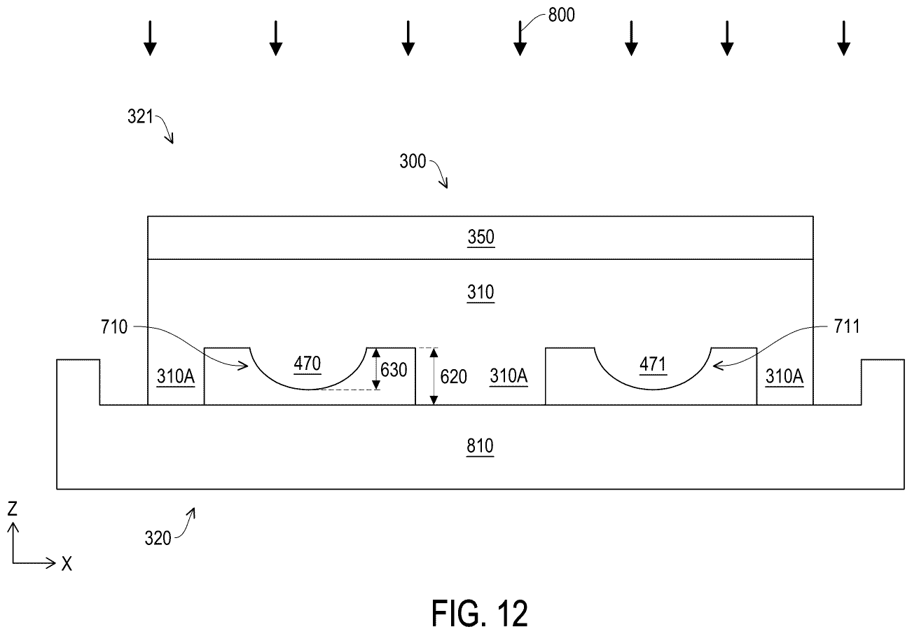

Referring now to FIG. 12, after removing the mask layer 510, additional processes 800 may be performed to the optical device 300. For example, one of the additional processes 800 may include a coupling process. In more detail, the optical device 300 may be flipped upside-down (i.e., with the side 321 now facing upwards and the side 320 now facing downwards) and placed on a carrier 810 (e.g., a chuck). In other words, the optical device 300 is coupled to the carrier 810 through the side 320. For reasons of simplicity, the ARC layer 770 is not specifically illustrated in FIG. 12, though it is understood that the ARC layer 770 is disposed between the carrier 810 and the rest of the optical device 300.

As shown in FIG. 12, the recesses 710 and 711 are trapped by the presence of the carrier 810. In other words, the recesses 710 and 711 may appear as cavities trapped between the carrier 810 and the rest of the optical device 300. Note that since the height 620 of the portion 310A of the silicon substrate 310 is greater than the height 630 of the microlenses 470 or 471, a gap separates the carrier 810 and the microlenses 470 or 471 in the Z-direction vertically. Such a vertical separation ensures that the microlenses 470 and 471 are protected from mechanical damage (e.g., a scratch against the microlens surface), contaminant particles, and/or environmental factors (e.g., excessive moisture) in the ensuing fabrication processes. Stated differently, the present disclosure specifically configures the dimensions of the microlenses 470 and 471, as well as surrounding portions 310A of the silicon substrate 310, to ensure that the microlenses 470 and 471 are safely housed within the recesses 710 and 711. Since the microlenses 470 and 471 are not exposed to external elements, potential damage to the microlenses 470 and 471 may be minimized. For example, the additional processes 800 may include additional fabrication processes performed to the optical device 300 from the side 321 (e.g., referred to as back side processing) while the optical device 300 is placed on the carrier 810. During these additional fabrication processes, the microlenses 470 and 471 are protected from potential damage and/or contamination.

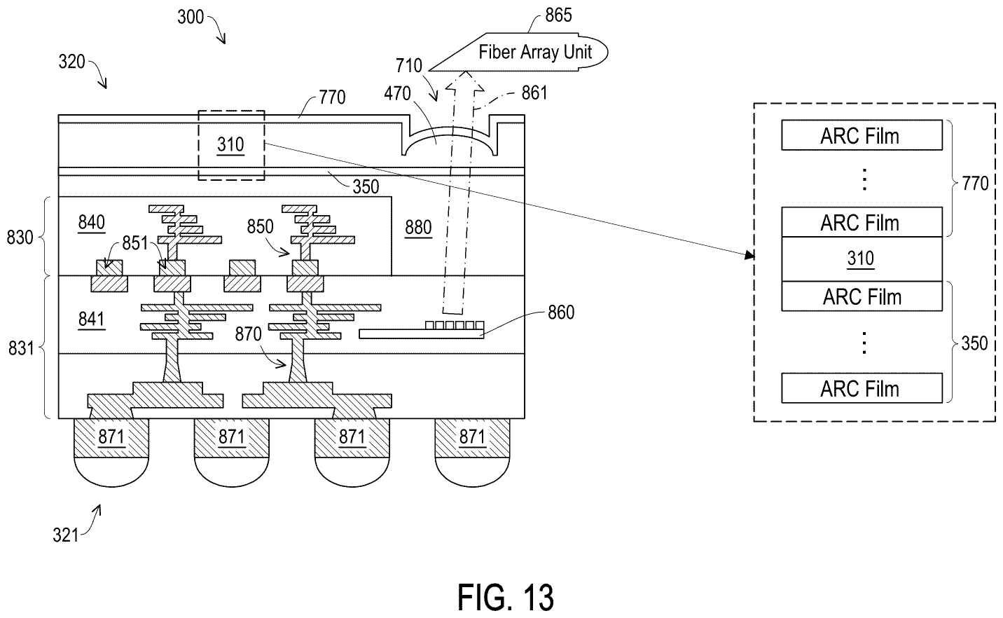

FIG. 13 illustrates the optical device 300 as a part of an optical engine that includes a photonic integrated circuit (PIC), an electronic integrated circuit (EIC), as well as a lens structure that includes the lens such as the microlenses 470-471 discussed above. Referring now to FIG. 13, the additional fabrication processes may form an EIC 830 and a PIC 831 on the side 321. The EIC 830 may serve as a central processing unit, which may include the controlling circuit (e.g., a microcontroller) for controlling the operation of the devices in the PIC 831. In addition, the EIC 830 may include the circuits for processing the electrical signals converted from the optical signals in the PIC 831. In some embodiments, the controlling circuit of the EIC 830 and/or the circuits for processing the electrical signals may be implemented using the FinFET devices or the GAA devices discussed above, which may be formed in a substrate 840 of the EIC 830 (e.g., a silicon substrate).

The EIC 830 may also include an interconnect structure 850, which may be comprised of a plurality of dielectric layers and metal lines and vias. The dielectric layers may also be formed of silicon oxide, silicon oxynitride, silicon nitride, or the like, or low-k dielectric materials having k values lower than about 3.0. The low-k dielectric materials may include Black Diamond (a registered trademark of Applied Materials), a carbon-containing low-k dielectric material, Hydrogen SilsesQuioxane (HSQ), MethylSilsesQuioxane (MSQ), or the like. The metal lines and vias may be formed using damascene processes, and may include, for example, copper on diffusion barrier layers. The diffusion barrier layers may be formed of titanium, titanium nitride, tantalum, tantalum nitride, or the like. A plurality of bonding pads, such as bonding pads 851, are formed over and connected to the metal lines/vias of the interconnect structure 850. The bonding pads 851 may be formed of aluminum and/or copper, or combinations thereof, but the disclosure is not limited thereto.

The PIC 831 may include a substrate 841, such as a semiconductor substrate (e.g., a silicon substrate), a dielectric substrate (e.g., a silicon oxide substrate), or a silicon-on-insulator (SOI) substrate. The PIC 831 includes an optical coupler 860, which is configured to be optically coupled to an optical signal source such as optical fibers, or the like. In some embodiments, the optical coupler 860 is a grating coupler, but the disclosure is not limited thereto. The top portions of the optical coupler 860 may have gratings, so that the optical coupler 860 may have the function of receiving light and/or transmitting light. In some embodiments, the optical coupler 860 used for receiving light receives the light from an overlying light source or optical signal source and transmit the light to a waveguide, which may be patterned by portions of the substrate 841. The optical coupler 860 used for transmitting light receives light from the waveguide and transmit light to an optical fiber array unit 865.

As such, the PIC 831 is configured to receive optical signals, transmitting the optical signals inside the PIC 831, transmit the optical signals out of the PIC 831, and communicate electronically with an electronic die (e.g., the EIC 830 shown in FIG. 13). Accordingly, the PIC 831 may also be responsible for the input-output (IO) of the optical signals. It is also understood that the PIC 831 may include active devices such as transistors (e.g., the FinFET devices or the GAA devices discussed above) and/or diodes (which may include photo diodes). The PIC 831 may also include passive devices such as capacitors, resistors, or the like. In some embodiments, no active devices are formed, while passive devices may be formed in the PIC 831.

The PIC 831 may also include an interconnect structure 870, which may also be comprised of a plurality of dielectric layers and metal lines and vias, similar to the interconnect structure 850. The interconnect structure 870 may include metal lines or bonding pads that are electrically and physically bonded to the bonding pads 851 of the EIC 830, which allows electrical connectivity between the EIC 830 and the PIC 831 to be established. The interconnect structure 870 may also include metal lines or bonding pads that are electrically and physically bonded to bonding pads 871 formed on the side 321, which may be used to help establish electrical connectivity between the microelectronic components of the optical device 300 and devices external to the optical device 300.

In some embodiments, the PIC 831 is in a wafer form, and the EIC 830 is a diced die that is picked and placed over the PIC 831. For example, the EIC 830 may be coupled to the PIC 831 a die-to-wafer bonding process. For example, a direct metal-to-metal thermal compression bonding, or any type of hybrid bonding technique, may be applied to facilitate the coupling of the EIC 830 and the PIC 831. An encapsulating material 880 may also be provided over the PIC 831. The encapsulating material 880 at least laterally encapsulates the EIC 830. In some embodiments, the encapsulating material 880 may be formed of a light-transparent material such as silicon oxide, or any other suitable oxide material. In some embodiments, an upper surface of the encapsulating material 880 may be higher than an upper surface of the EIC 830. For example, the encapsulating material 880 may cover the upper surface of the EIC 830.

In the embodiment of FIG. 13, a light source and/or receiver, may be positioned over (e.g., vertically aligned with) one or more of the microlenses, such as over the microlens 470. For example, the Fiber Array Unit 865, as a light receiver, may be positioned over and aligned with the one or more microlenses 470. The fiber array unit 865 may include an array of units that are each configured to receive light, such as the light 861. The light 861 may propagate through the microlens 470, which may help focus the light 861 with respect to the optical coupler 860. As discussed above, the unique fabrication process flow of the present disclosure embeds the microlens 470 within the recess 710, which is defined by patterning the silicon substrate 310 to ensure that the microlens 470 has a lower height than the portions of the silicon substrate 310 that surrounds the microlens 470. As a result, the microlens 470 may be protected from accidental damage (e.g., scratches) and/or contamination. Furthermore, by implementing the microlens 470 with a silicon material-which is more durable and less likely to suffer from deformation—the microlens 470 may be able to focus the light with better precision.

Note that FIG. 13 also provides a magnified view of a portion of the optical device 300 (corresponding to what is included in the dashed box). In more detail, the layers 770 disposed on the side 320 of the silicon substrate 310 may include a plurality of ARC films, and the layers 350 disposed on the side 321 of the silicon substrate 310 may also include a plurality of ARC films as well. Such a multi-film aspect of the layers 770 and 350 is illustrated clearly in the magnified view. By implementing one or more ARC films on both sides of the silicon substrate 310, the optical device 300 can achieve a smaller insertion loss, since less light will be wasted due to undesirable reflection and/or refraction.

FIG. 14 illustrates an integrated circuit fabrication system 900 that may be used to fabricate the optical device 300 according to embodiments of the present disclosure. The fabrication system 900 includes a plurality of entities 902, 904, 906, 908, 910, 912, 914, 916 . . . , N that are connected by a communications network 918. The network 918 may be a single network or may be a variety of different networks, such as an intranet and the Internet, and may include both wire line and wireless communication channels.

In an embodiment, the entity 902 represents a service system for manufacturing collaboration; the entity 904 represents an user, such as product engineer monitoring the interested products; the entity 906 represents an engineer, such as a processing engineer to control process and the relevant recipes, or an equipment engineer to monitor or tune the conditions and setting of the processing tools; the entity 908 represents a metrology tool for IC testing and measurement; the entity 910 represents a semiconductor processing tool, such an EUV tool that is used to perform lithography processes to define the various components of a transistor; the entity 912 represents a virtual metrology module associated with the processing tool 910; the entity 914 represents an advanced processing control module associated with the processing tool 910 and additionally other processing tools; and the entity 916 represents a sampling module associated with the processing tool 910.

Each entity may interact with other entities and may provide integrated circuit fabrication, processing control, and/or calculating capability to and/or receive such capabilities from the other entities. Each entity may also include one or more computer systems for performing calculations and carrying out automations. For example, the advanced processing control module of the entity 914 may include a plurality of computer hardware having software instructions encoded therein. The computer hardware may include hard drives, flash drives, CD-ROMs, RAM memory, display devices (e.g., monitors), input/output device (e.g., mouse and keyboard). The software instructions may be written in any suitable programming language and may be designed to carry out specific tasks.

The integrated circuit fabrication system 900 enables interaction among the entities for the purpose of integrated circuit (IC) manufacturing, as well as the advanced processing control of the IC manufacturing. In an embodiment, the advanced processing control includes adjusting the processing conditions, settings, and/or recipes of one processing tool applicable to the relevant wafers according to the metrology results.

In another embodiment, the metrology results are measured from a subset of processed wafers according to an optimal sampling rate determined based on the process quality and/or product quality. In yet another embodiment, the metrology results are measured from chosen fields and points of the subset of processed wafers according to an optimal sampling field/point determined based on various characteristics of the process quality and/or product quality.

One of the capabilities provided by the IC fabrication system 900 may enable collaboration and information access in such areas as design, engineering, and processing, metrology, and advanced processing control. Another capability provided by the IC fabrication system 900 may integrate systems between facilities, such as between the metrology tool and the processing tool. Such integration enables facilities to coordinate their activities. For example, integrating the metrology tool and the processing tool may enable manufacturing information to be incorporated more efficiently into the fabrication process or the APC module, and may enable wafer data from the online or in site measurement with the metrology tool integrated in the associated processing tool.

FIG. 15 is a flowchart of a method 1000 of fabricating a semiconductor device according to various aspects of the present disclosure. The method 1000 includes a step 1010 to form a sacrificial component over a first side of a substrate. The sacrificial component has a first curved profile in a cross-sectional side view. In some embodiments, the sacrificial component is formed via a lithography process or a dispensing process.

The method 1000 includes a step 1020 to perform one or more first etching processes to the sacrificial component and the substrate from the first side. The one or more first etching processes remove the sacrificial component and defines a first portion of the substrate below the sacrificial component as a microlens. The microlens has a second curved profile in the cross-sectional side view. In some embodiments, the first curved profile and the second curved profile have different degrees of curvature. In some embodiments, the sacrificial component and the microlens have substantially similar dimensions in a horizontal direction in the cross-sectional side view. In some embodiments, the one or more first etching processes include an anisotropic etching process. In some embodiments, the anisotropic etching process includes an inductively coupled plasma reactive-ion etching process. In some embodiments, the anisotropic etching process is performed using a fluorine-based etchant. In some embodiments, the fluorine-based etchant includes CHF₃, CF₄, C₄F₈, NF₃, SF₆. In some embodiments, the anisotropic etching process is performed using a reactive gas or a diluting gas. In some embodiments, the mask layer is formed at least in part by defining a metal layer or a polymer layer using a lithography process.

The method 1000 includes a step 1030 to form a mask layer over the first side of the substrate. The mask layer surrounds the microlens in the cross-sectional side view. The mask layer and the substrate have different material compositions.

The method 1000 includes a step 1040 to perform one or more second etching processes to the mask layer and the substrate from the first side. The mask layer is etched at a slower rate than the substrate, such that the microlens has a smaller height than a second portion of the substrate below the mask layer in the cross-sectional side view after the one or more second etching processes have been completed. In some embodiments, the one or more second etching processes include an anisotropic etching process. In some embodiments, the mask layer is formed to have a greater height than the microlens in the cross-sectional side view before the one or more second etching processes are performed.

The method 1000 includes a step 1050 to remove the mask layer.

It is understood that the method 1000 may include further steps performed before, during, or after the steps 1010-1050. For example, before the step 1010 is performed to form the sacrificial component, the method 1000 may include a step of forming one or more material layers over a second side of the substrate opposite the first side. The one or more material layers may include a circuit layer or an antireflection coating layer. As another example, after the mask layer is removed in step 1050, the method 1000 may include a step of forming an antireflection coating layer over the first side of the substrate, including over an upper surface of the microlens, as well as a step of bonding the first side of the substrate to a chuck. A gap is formed between the chuck and the first side of the substrate after the bonding. The microlens is disposed within the gap. For reasons of simplicity, other additional steps are not discussed herein in detail.

In summary, the present disclosure involves a unique process flow for forming silicon microlenses within a recess for an optical device. For example, curved sacrificial components may be formed over a front side of a silicon substrate, and anisotropic etching processes may be performed from the front side to gradually transfer the curved profile of the sacrificial components to portions of the silicon substrate, thereby forming silicon-based microlenses. Thereafter, a patterned mask layer may be formed to surround the microlenses laterally. The silicon substrate and the microlenses may then be etched from the front side while the patterned mask layer serves as a protective mask, which allows the portions of the silicon substrate protected by the mask layer to have greater heights than the microlenses at the completion of the etching. The mask layer is then removed, and the front side of the optical device is attached to a carrier. Additional processing of the optical device may then be performed from the back side.

The embodiments of the present disclosure offer advantages. It is understood, however, that other embodiments may offer additional advantages, and not all advantages are necessarily disclosed herein, and that no particular advantage is required for all embodiments. One advantage is the improved yield of the optical device. In more detail, microlenses in optical devices have typically been formed using a polymer material. However, polymer is vulnerable to potential deformation, for example, due to an application of mechanical forces and/or environmental conditions, such as high temperature. The deformation of microlenses may render the optical device defective and therefore decreases the yield. Here, by implementing portions of a silicon substrate as the microlenses, the microlenses are more durable, have better structural integrity, and are less likely to become deformed. Consequently, device yield may be improved. In addition, existing methods of implementing microlenses may leave them exposed (e.g., protruding away from a substrate) to external elements. As such, the microlenses may suffer from scratches and/or other types of accidental damage. Here, the microlenses are protected by the surrounding portions of the silicon substrate that have taller heights. In other words, since the microlenses are each located within a recess, they are less likely to suffer accidental damage such as scratches. Due to the location in the recesses, the microlenses may also be protected from contamination and/or other environmental factors. For these reasons, the optical devices herein may offer better yield.

Another advantage is enhanced performance of the optical device. As discussed above, the polymer-based microlenses may be prone to deformation. When such deformation occurs, the polymer-microlenses may not be able to focus the light on the intended targets with precision. In contrast, the silicon-based microlenses are less likely to become deformed. In addition, the fact that the silicon-based microlenses are embedded in the recesses of the silicon substrate further protects the silicon-based microlenses from potential damage, which means that the silicon-based microlenses herein are able to focus the light on their intended targets with improved precision. Furthermore, the implementation of antireflection layers on both sides of the silicon substrate can effectively reduce undesirable light reflection and/or refraction. This further reduces insertion loss and improves the performance of the optical devices herein. Other advantages may include compatibility with existing fabrication processes and the ease and low cost of implementation.

One aspect of the present disclosure pertains to a method. According to the method, a sacrificial component over a first side of a substrate. The sacrificial component has a first curved profile in a cross-sectional side view. One or more first etching processes are performed to the sacrificial component and the substrate from the first side. The one or more first etching processes remove the sacrificial component and defines a first portion of the substrate below the sacrificial component as a microlens. The microlens has a second curved profile in the cross-sectional side view. A mask layer is formed over the first side of the substrate. The mask layer surrounds the microlens in the cross-sectional side view. The mask layer and the substrate have different material compositions. One or more second etching processes are performed to the mask layer and the substrate from the first side. The mask layer is etched at a slower rate than the substrate, such that the microlens has a smaller height than a second portion of the substrate below the mask layer in the cross-sectional side view after the one or more second etching processes have been completed. The mask layer is then removed.

Another aspect of the present disclosure pertains to a method. According to the method, a sacrificial component is formed on a front side of a silicon wafer. The sacrificial component has a first curved shape in a cross-sectional side view. A first etching process is performed to the sacrificial component and the silicon wafer from the front side until the sacrificial component is removed. A first portion of the silicon wafer below the sacrificial component is etched into a microlens that has a second curved shape in the cross-sectional side view. A mask layer is formed over the front side of the silicon wafer. The mask layer defines a recess within which the microlens is located in the cross-sectional side view. The mask layer contains a metal material or a polymer material. A second etching process is performed to the microlens and the silicon wafer from the front side, thereby extending the recess toward a back side of the silicon wafer. The mask layer protects a second portion of the silicon wafer from being etched. The mask layer is removed.

Another aspect of the present disclosure pertains to a structure. The structure includes a silicon substrate. The structure includes a silicon microlens that protrudes out of a first side of the silicon substrate. The silicon microlens has a curved surface and is surrounded laterally by a portion of the silicon substrate that also protrudes of the first side. The portion of the silicon substrate has a greater height than the silicon microlens. The structure includes one or more antireflection coating layers disposed over the first side of the silicon substrate, including over the silicon microlens and over the portion of the silicon substrate. The structure includes one or more material layers disposed over a second side of the silicon substrate opposite the first side.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a sacrificial component over a first side of a substrate, wherein the sacrificial component has a first curved profile in a cross-sectional side view;
performing one or more first etching processes to the sacrificial component and the substrate from the first side, wherein the one or more first etching processes remove the sacrificial component and defines a first portion of the substrate below the sacrificial component as a microlens, wherein the microlens has a second curved profile in the cross-sectional side view;
forming a mask layer over the first side of the substrate, wherein the mask layer surrounds the microlens in the cross-sectional side view, and wherein the mask layer and the substrate have different material compositions;
performing one or more second etching processes to the mask layer and the substrate from the first side, wherein the mask layer is etched at a slower rate than the substrate, such that the microlens has a smaller height than a second portion of the substrate below the mask layer in the cross-sectional side view after the one or more second etching processes have been completed; and
removing the mask layer.

2. The method of claim 1, wherein the sacrificial component is formed via a lithography process or a dispensing process.

3. The method of claim 1, further comprising, before the forming the sacrificial component, forming one or more material layers over a second side of the substrate opposite the first side, wherein the one or more material layers include a circuit layer or an antireflection coating layer.

4. The method of claim 1, further comprising, after the removing of the mask layer:
forming an antireflection coating layer over the first side of the substrate, including over an upper surface of the microlens; and
bonding the first side of the substrate to a chuck, wherein a gap is formed between the chuck and the first side of the substrate after the bonding, and wherein the microlens is disposed within the gap.

5. The method of claim 1, wherein the first curved profile and the second curved profile have different degrees of curvature.

6. The method of claim 1, wherein the sacrificial component and the microlens have substantially similar dimensions in a horizontal direction in the cross-sectional side view.

7. The method of claim 1, wherein at least some of the one or more first etching processes or the one or more second etching processes include an anisotropic etching process.

8. The method of claim 7, wherein the anisotropic etching process includes an inductively coupled plasma reactive-ion etching process.

9. The method of claim 7, wherein the anisotropic etching process is performed using a fluorine-based etchant.

10. The method of claim 9, wherein the fluorine-based etchant includes CHF₃, CF₄, C₄F₈, NF₃, SF₆.

11. The method of claim 7, wherein the anisotropic etching process is performed using a reactive gas or a diluting gas.

12. The method of claim 1, wherein the mask layer is formed at least in part by defining a metal layer or a polymer layer using a lithography process.

13. The method of claim 1, wherein the mask layer is formed to have a greater height than the microlens in the cross-sectional side view before the one or more second etching processes are performed.

14. A method, comprising:
forming a sacrificial component on a front side of a silicon wafer, wherein the sacrificial component has a first curved shape in a cross-sectional side view;
performing a first etching process to the sacrificial component and the silicon wafer from the front side until the sacrificial component is removed, wherein a first portion of the silicon wafer below the sacrificial component is etched into a microlens that has a second curved shape in the cross-sectional side view;
forming a mask layer over the front side of the silicon wafer, wherein the mask layer defines a recess within which the microlens is located in the cross-sectional side view, and wherein the mask layer contains a metal material or a polymer material;
performing a second etching process to the microlens and the silicon wafer from the front side, thereby extending the recess toward a back side of the silicon wafer, wherein the mask layer protects a second portion of the silicon wafer from being etched; and
removing the mask layer.

15. The method of claim 14, wherein the recess is extended by the second etching process such that the second portion of the silicon wafer has a greater vertical dimension than the microlens in the cross-sectional side view.

16. The method of claim 14, further comprising:
forming one or more first antireflection coating layers over the back side of the silicon wafer before the forming of the sacrificial component; and
forming one or more second antireflection coating layers over the front side of the silicon wafer after the removing of the mask layer, including over the microlens and the second portion of the silicon wafer.

17. The method of claim 16, further comprising:
attaching the front side of the silicon wafer to a chuck, wherein a gap separates the microlens from the chuck; and
performing additional fabrication processes to the silicon wafer from the back side after the attaching.

18. A structure, comprising:
a silicon substrate;
a silicon microlens that protrudes out of a first side of the silicon substrate, wherein the silicon microlens has a curved surface and is surrounded laterally by a portion of the silicon substrate that also protrudes of the first side, and wherein the portion of the silicon substrate has a greater height than the silicon microlens;
one or more antireflection coating layers disposed over the first side of the silicon substrate, including over the silicon microlens and over the portion of the silicon substrate; and
one or more material layers disposed over a second side of the silicon substrate opposite the first side.

19. The structure of claim 18, wherein the one or more material layers include one or more circuit-containing layers or one or more additional antireflection coating layers.

20. The structure of claim 18, wherein the silicon substrate and the silicon microlens have identical material compositions.
